(19) United States
(12) Patent Application Publication
(10) Pub. No.: US 2020/0140991 A1
(43) Pub. Date: May 7, 2020

(54) EVAPORATION DEVICE FOR A VACUUM EVAPORATION SYSTEM, APPARATUS AND METHOD FOR DEPOSITING A FILM OF MATERIAL

(71) Applicant: RIBER, BEZONS (FR)

(72) Inventors: Youri ROUSSEAU, Maisons Laffitte (FR); Jean-Louis GUYAUX, La Vernelle (FR); Franck STEMMELEN, Vaureal (FR)

(21) Appl. No.: 16/675,549

(22) Filed: Nov. 6, 2019

(30) Foreign Application Priority Data
Nov. 6, 2018 (FR) 18 60207

(51) Int. Cl. C23C 14/24; C23C 14/26

(52) U.S. Cl. CPC C23C 14/243; C23C 14/26

(57) ABSTRACT

Disclosed is an evaporation device including an evaporation cell including heating element and a crucible having an upper open end and a lower closed bottom, intended to receive a load, the device being adapted to generate a flow of vapour-phase material by evaporation or sublimation of the load material. The evaporation device includes a filtering insert including an upper part having a conical opening intended to be placed at the open end of the crucible, and a lower part including, from the top to the bottom, a plate having at least one opening and one grid, the lower part being intended to be placed in the crucible between the upper part and the load. Also disclosed is an apparatus and a method for depositing a film of material on a substrate.

### TECHNICAL FIELD TO WHICH THE INVENTION RELATES

The present invention generally relates to the field of vacuum thin-film material deposition equipment.

It more particularly relates to methods and apparatuses for vapour deposition of material on a substrate.

More particularly, the present invention applies to thin-film deposition of inorganic and organic materials.

### TECHNOLOGICAL BACK-GROUND

Methods and apparatuses for vapour deposition of material on a substrate are known from the prior documents US 2007/074654 and U.S. Pat. No. 5,104,695. Generally, material deposition is performed in a vacuum chamber comprising heating means, a vacuum pump and an effusion cell, also called evaporation cell, in which the source material to be evaporated is placed. The source material to be evaporated is heated to a temperature higher than about 150° C. and evaporates inside the effusion cell. In practice, the effusion cell has at least one opening for the vapour-phase material to pass through towards the substrate. Hence, in contact with the substrate, the vapour-phase material deposit condenses to form a thin film of solid material. That way, it is possible to deposit a layer of material or to superimpose successively several thicknesses of thin films of material.

The effusion cells involved in the evaporation methods for depositing a film of material on a substrate comprise several elements, including a crucible and heating means. The heating means are generally arranged about the crucible. The crucible generally has an upper open end and a lower closed bottom in which the source material is placed. The upper open end of the crucible allows the material evaporated into vapour phase to pass through towards the substrate. Often, an insert having an opening of predetermined size is placed on the upper open end of the crucible. The insert has for main function to control the dispersion of the flow of evaporated material at the exit of the effusion cell. This insert also makes it possible, for example, to limit the passage of solid and/or liquid material spatters generated during the evaporation of the source material on the substrate. These material spatters create non-uniformities or defects in the film(s) of deposited material. The insert also allows improving the reproducibility of the thickness of a film during its formation on a substrate.

However, the presence of an opening on the insert leads to a high loss of heat at the upper end of the crucible that generates a phenomenon of condensation and hence a clogging of the insert opening. The clogging of the insert opening may make the material deposition flow unstable during the method of deposition of material on a substrate. This phenomenon of material condensation on the insert is all the more accelerated when the vaporization temperature of the source material is low, i.e. for a temperature lower than or equal to 600° C.

In case of deposition of magnesium, for example for the manufacturing of large size organic light-emitting diode (OLED) screens, the temperature of the crucible is relatively low, of the order of 400° C. The loss of heat through the insert opening cools the insert and causes a partial condensation of the vapour-phase material on the insert walls. This condensation on the insert modifies the dispersion of the flow of evaporated material towards the substrate, which makes it very difficult to obtain a uniform-thickness, reproducible and flawless deposit.

It is hence necessary to develop an evaporation device and method for avoiding the insert opening clogging problems while reducing the risk of solid and/or liquid material spatters of the substrate.

One of the objects of the invention is to deposit a thin film of the organic and inorganic materials whose vapour pressure is comprised between 10⁻³ mbar and 1 mbar at a temperature comprised between 100° C. and 600° C.

### OBJECT OF THE INVENTION

In order to remedy the above-mentioned drawbacks of the state of the art, the present invention proposes an evaporation device comprising an evaporation cell including heating means and a crucible having an upper open end and a lower closed bottom, intended to receive a load of material to be evaporated or sublimated, the heating means being adapted to heat the crucible containing the load and to generate a flow of vapour-phase material by evaporation or sublimation of the load material.

According to the invention, the evaporation device further includes a filtering insert comprising: an upper part having a conical opening intended to be placed at the open end of the crucible, and a lower part comprising, from the top to the bottom, a plate having at least one opening and one grid, the lower part being intended to be placed into the crucible between the upper part and the load.

The evaporation device of the present invention advantageously allows improving the uniformity and homogeneity of the thin-film deposition on a substrate and avoids the solid and/or liquid material spatters coming from the evaporation or the sublimation of the load towards the substrate.

More particularly, the lower part of the filtering insert comprises, from the top to the bottom, another plate having at least one other opening, the plate having at least one opening and the grid.

Particularly advantageously, the heating means comprise a first heating area and a second heating area, the first heating area being arranged in a lower part of the evaporation cell and the second heating area being arranged in an upper part of the effusion cell.

Still more advantageously, the plate is placed above the lower part of the evaporation cell, for example between the first heating area and the second heating area or in the second heating area.

According to the invention, said at least one opening of said plate and said at least one other opening of said other plate are staggered.

Advantageously, the total surface of said at least one opening of said plate is lower than or equal to 1% of the surface of said plate.

According to another embodiment, the lower part comprises, from the top to the bottom, said plate, the grid and another grid, the grid having pores of smaller size than the pores of said other grid.

According to an embodiment, the conical opening of the filtering insert forms a cone of revolution having a truncated apex and a base.

Advantageously, the filtering insert comprises a cap having an opening placed around the conical opening of the filtering insert, said cap being adapted to thermally isolate the crucible.

The evaporation device may further include fixation means between the lower part and the upper part of the filtering insert.

The invention also proposes an apparatus for depositing a film of material on a substrate, comprising the evaporation device according to the invention and a vacuum deposition chamber, said deposition apparatus being adapted to deposit at least one film of said vapour-phase material on a substrate.

The invention also proposes a method for depositing a film of material on a substrate, comprising the following steps:
positioning a load of material to be evaporated or sublimated into the bottom of the crucible of a deposition apparatus according to the invention,
vacuuming the chamber by pumping it,
heating a crucible containing the load so as to generate a flow of vapour-phase material by evaporation or sublimation of the load,
filtering solid and/or liquid material through the filtering insert, while letting the flow of vapour-phase material passing through the conical opening, and
depositing the film of said vapour-phase material on the substrate.

### DETAILED DESCRIPTION OF AN EXEMPLARY EMBODIMENT

The following description in relation with the appended drawings, given by way of non-limitative examples, will allow a good understanding of what the invention consists of and of how it can be implemented.

In the appended drawings:

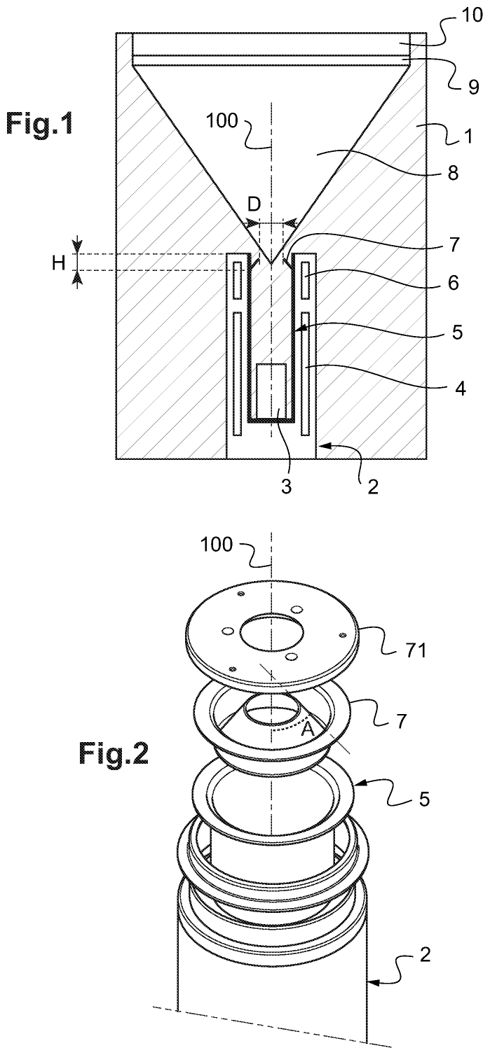

FIG. 1 schematically shows a vacuum material deposition apparatus according to the prior art,

FIG. 2 is an exploded view of an effusion cell according to the prior art,

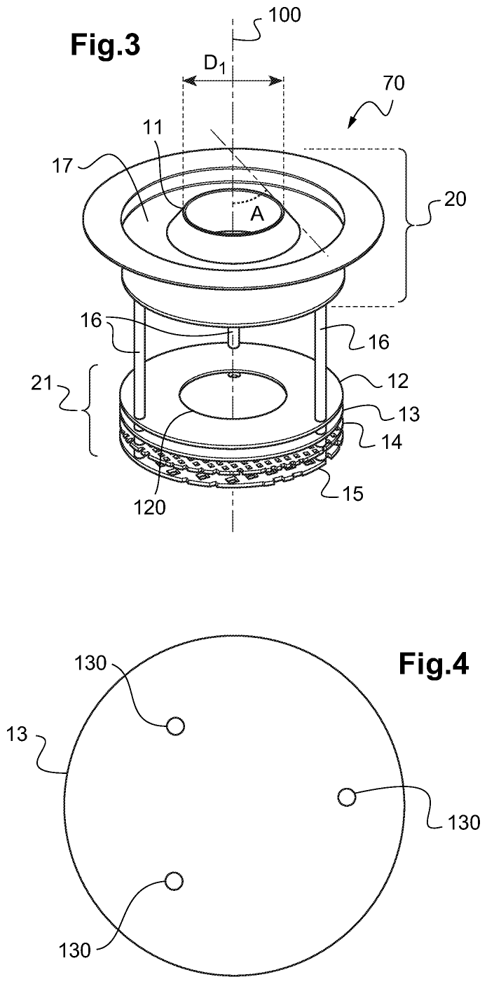

FIG. 3 is a perspective view of a filtering insert according to an exemplary embodiment of the present invention,

FIG. 4 is a front view of an example of plate having three circular openings,

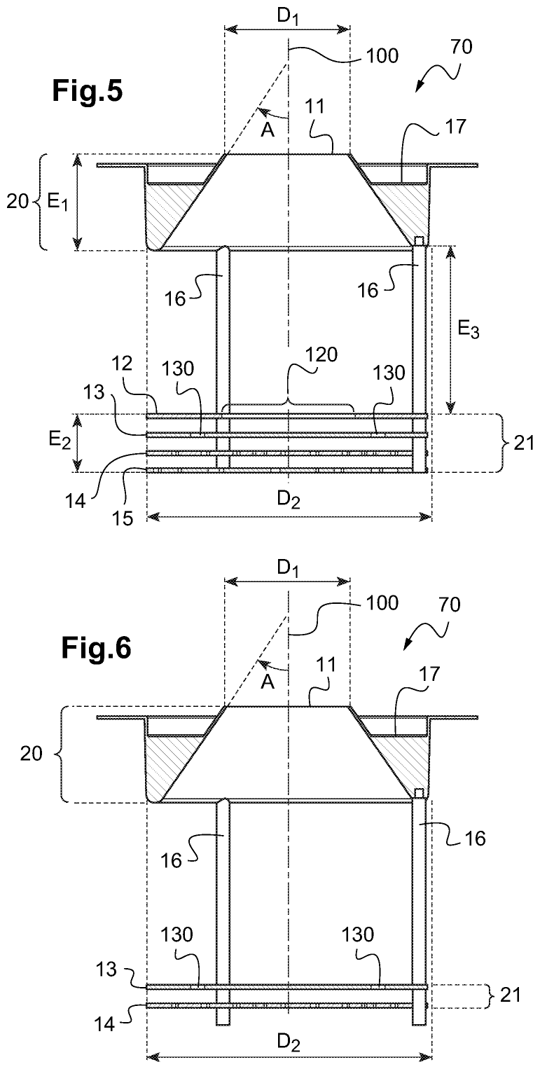

FIG. 5 is a cross-sectional view of a filtering insert according to an exemplary embodiment of the present invention,

FIG. 6 is a cross-sectional view of a filtering insert according to another exemplary embodiment of the present invention.

### DEVICE AND METHOD

In FIG. 1 is shown a sectional view of an example of vacuum material deposition apparatus according to the prior art. The apparatus comprises a vacuum chamber 1 in which are placed an effusion cell 2, also called evaporation cell, and a substrate 10. The chamber is kept under vacuum thanks to a vacuum pump, for example. The substrate 10 is positioned at a predetermined distance from the effusion cell 2 so as to control the formation of the thin-film material deposit 9 on the substrate 10. The size of the substrate 10 may vary in a range from 10 mm×10 mm to 2000 mm×2000 mm. The thickness of the thin film deposited is generally comprised between 0.1 nm and 1000 nm. The effusion cell 2 comprises a crucible 5 and heating means 4 and 6. The crucible 5 comprises, in upper part, an open opening and, in lower part, a closed bottom. The source material, also called load, is deposited into the lower closed bottom of the crucible 5. The load 3 is generally deposited into the crucible 5 is solid form. After heating, according to the material and the heating temperature, the load remains solid or is transformed into a liquid. A solid load is intended to be sublimed into vapour phase and a liquid phase is intended to be evaporated into vapour phase. Generally, the initial height of the load corresponds to the third of the height of the crucible 5. The load is for example chosen among the materials having an evaporation temperature comprised between 150° C. and 1500° C. or a sublimation temperature comprised between 150° C. and 1500° C.

In this example, the heating means are divided into two parts: a first heating area 4 and a second heating area 6. The first heating area 4 is placed in the lower part of the effusion cell 2, which extends for example up from the bottom, over two-thirds of the height of the effusion cell 2. The second heating area 6 is placed in the upper part of the effusion cell 2, extending for example down from the open end of the crucible 5, over the third of the height of the effusion cell 2.

The heating means may for example comprise a plurality of heating resistors. Generally, the heating means are arranged around the external part of the crucible 5. The crucible 5 is for example removable. In FIG. 1, the heating means are arranged around the lateral walls of the crucible. The heating temperature ranges of the crucible are comprised between 150° C. and 1500° C. according to the material of the load used.

An insert 7 is arranged on the upper open end of the crucible 5. The insert 7 is for example an insert forming a sheet-metal cap comprising a conical opening to control the flow of material 8 to be deposited on the substrate 10.

FIG. 2 is an exploded view of the effusion cell described in connection with FIG. 1. The crucible 5 is for example made of a material chosen among pyrolytic boron nitride or tantalum.

In this embodiment, the crucible 5 has the shape of a circular cross-section cylinder, closed at one end and open at the other end. The geometry and shape of the crucible 5 are non-limitative parameters.

The insert 7 comprises a conical opening, for example of circular cross-section. The conical opening is defined by geometric parameters such as opening angle A with respect to the cylinder axis 100, and opening height H and diameter D. The insert 7 may for example be made of a material chosen among tantalum or boron nitride. The conical shape of the insert 7 allows controlling the flow of vapour-phase material and hence controlling the uniformity of the material deposition on the substrate. The insert 7 is adapted to be fixed to the open end of the crucible.

Advantageously, a cap 71 having an opening whose diameter is higher by a few millimetres (for example, between 2 mm and 3 mm) than that of the insert opening is superimposed to the insert 7. The cap allows keeping the heat in the cell, which allows limiting the thermal radiation of the effusion cell. The cap 71 is for example arranged on top of the effusion cell.

However, in the case of evaporation of magnesium for the manufacturing of large size organic light-emitting diode screens, the evaporation of magnesium is performed in a relatively low range of temperature comprised between 400° C. and 500° C. An observation that is part of the present disclosure is that this low temperature evaporation may cause a phenomenon of magnesium condensation on the walls of the insert 7. This magnesium condensation phenomenon modifies the flow exiting from the effusion cell and finally clogs the insert opening. Moreover, the evaporation of magnesium causes the formation of a deposit of undesirable ashes on the substrate, so that the method of manufacturing large size organic light-emitting diode screens is hence not very robust and very random.

FIG. 3 schematically shows a perspective view of a filtering insert 70 according to an example of the present disclosure. The evaporation device comprises at least one heating means, a crucible 5 similar to that described hereinabove in FIGS. 1 and 2 and a filtering insert 70. The heating means has at least one heating area located around or inside the walls of the crucible. The heating means comprises for example a plurality of electric resistors.

The filtering insert 70 comprises an upper part 20 provided with a conical opening 11 of diameter D1 intended to be arranged at the open end of the crucible and a lower part 21 comprising at least one plate and at least one grid.

In the example shown in FIG. 3, the lower part 21 of the filtering insert 70 comprises, from the top to the bottom, two plates and two grids. The two plates comprise, from the bottom to the top, a plate 13 having at least one opening 130 and another plate 12 having at least one other opening 120. The two grids comprise, from the top to the bottom, a grid 14 and another grid 15. The lower part 21 is intended to be arranged in the crucible between the upper part 20 and the load 3 in the bottom of the crucible.

Said at least one other opening 120 of said other plate 12 (illustrated in FIG. 3) and said at least one opening 130 of said plate 13 (illustrated in FIG. 4) are staggered so as to prevent the passage of solid and/or liquid material between the inside and the outside of the crucible through the conical opening, in particular during an evaporation or a vaporisation of the load.

In the example shown, the crucible having a circular cross-section, said other plate 12 has the shape of a washer with a hole in the centre and the plate 13 has the shape of a disc pierced with several openings. However, these shapes are not limitative in any way.

FIG. 4 shows an example of the plate 13 with its openings 130. Herein, the plate 13 has for example three circular openings 130 arranged off-axis. The diameter of the circular openings 130 of the plate 13 is comprised between 0.5 mm and 10 mm. The number and the geometry of the opening 130 being not limitative.

The grid 14 has pores of smaller size than the pores of said other grid 15, so as to filter the solid and/or liquid material generated during the evaporation or the vaporisation of the load.

In the embodiment illustrated in FIG. 5, the upper part 20 of the filtering insert 70 has a cylindrical external shape and a conical opening 11 of inner diameter D1. The inner diameter D1 of the conical opening 11 is comprised between 2 mm and 100 mm. Preferably, the inner diameter D1 of the conical opening 11 is lower than or equal to half the inner diameter of the crucible. The upper part 20 of the filtering insert has a height E1 comprised between 5 mm and 80 mm. In FIG. 5, the height E1 corresponds to the distance separating the apex of the conical opening 11 of diameter D1 and the base of the conical opening 11.

The upper part 20 of the filtering insert has an outer diameter D2 slightly lower than the inner diameter of the crucible to allow the insertion and/or extraction of the filtering insert after having placed the load into the crucible.

The lower part 21 of the filtering insert has a height E2 comprised between 3 mm and 40 mm, preferably between 8 mm and 25 mm. In FIG. 5, the height E2 corresponds to the distance that separates the face of said other plate 12 turned towards the opening of the crucible and the face of said other grid 15 directed towards the bottom of the crucible.

The upper part 20 and the lower part 21 of the filtering insert may be removable and independent from each other. The upper part 20 and the lower part 21 of the filtering insert are for example connected to each other thanks to a fixation system comprising a plurality of rods or posts 16, as illustrated in FIG. 3. As a variant, the upper part 20 and the lower part 21 may be connected to each other by a tube, possibly pierced with a plurality of holes to reduce the phenomenon of thermal screening. Another variant consists in fixing the lower part 21 of the filtering insert to an inner edge of the crucible and, separately, the upper part 20 to the open end of the crucible. The height E3 corresponding to the distance separating the upper part 20 from the lower part 21 of the filtering insert is comprised between 20 mm and 80 mm. Preferably, the height E3 is defined so as to place the plate 13 between the two heating areas. According to a variant, the plate 13 is arranged in the upper part of the effusion cell 2, in other words at the second heating area 6. In this variant, the plate 13 is also arranged above the lower part of the effusion cell surrounded by the first heating area 4. In any case, the insert 70 is located above the lower part of the effusion cell surrounded by the first heating area 4. This arrangement of the insert 70—and in particular the plate 13 between the two heating areas or in the second heating area 6, and still above the lower part of the effusion cell 2—allows the thermal uncoupling between the upper part and the lower part of the effusion cell 2.

The conical opening 11 of the filtering insert forms for example a cone of revolution about the axis 100, the cone having a truncated apex. The truncated apex defines the conical opening of the filtering insert. For example, the conical opening of the filtering insert has an opening angle A with respect to the axis 100 of the crucible comprised between 0° and 60°, a height E1 defined between the apex and the base of the conical opening 11 comprised between 5 mm and 80 mm, and an opening diameter D1 comprised between 2 mm and 100 mm. Preferably, the inner diameter D1 of the conical opening 11 is lower than or equal to half the inner diameter of the crucible, Advantageously, the height E1 is higher than the third of the height of the second heating area 6 of the effusion cell 2. The truncated apex of the conical opening 11 may be directed towards the substrate 10 or, at the opposite, towards the bottom of the crucible.

The material of the conical opening may be chosen among tantalum, molybdenum, stainless steel, titanium, niobium, tungsten or graphite. According to the material, the conical opening may be made by stamping or by machining. As an alternative, the conical opening may be made by growth of pyrolytic boron nitride on a support such as a mandrel.

The shape of the conical opening 11 of the filtering insert is non-limitative and varies as a function of each application.

Optionally, the filtering insert shown in FIG. 3 has a groove 17 located about the conical opening 11. The disc-shaped groove 17 makes it possible for example to place a cap with an opening arranged so as to be aligned with the conical opening of the filtering insert. Said cap is adapted to thermally isolate the crucible and hence to limit the thermal radiation of the substrate. The cap also allows keeping the maximum of heat in the effusion cell and limits the phenomenon of condensation on the filtering insert. The cap is made of a material chosen among tantalum, molybdenum or stainless steel.

The material of the plates 12 and 13 and grids 14 and 15 is chosen among the following materials: stainless steel, tantalum, molybdenum, titanium, nickel, niobium, tungsten, graphite, pyrolytic graphite, pyrolytic boron nitride, alumina or ceramic materials.

In certain applications, the material of the elements of the upper part 20 and of the lower part 21 of the filtering insert is stainless steel. However, the choice of the material for the elements of the upper part 20 or of the posts 16 depends on each application.

The material of the posts 16 is chosen among the following materials: tantalum, molybdenum, stainless steel, titanium, niobium, or tungsten.

The load material to be used is chosen among the following materials: silver, arsenic, barium, beryllium, bismuth, calcium, cadmium, caesium, cupper, dysprosium, erbium, europium, gallium, mercury, indium, potassium, lutetium, magnesium, sodium, neodymium, phosphorus, lead, rubidium, sulphur, antimony, selenium, samarium, tin, strontium, tellurium, thallium, ytterbium, zinc, metal halide, metal chalcogenide, oxide or organic materials.

The evaporation device provided with the filtering insert 70 is adapted to evaporate or sublimate for example materials having a high vapour pressure in a relatively low range of temperature comprised between 150° C. and 500° C., such as magnesium.

Said other plate 12 has at least one other opening 120, for example circular in shape, and centred on the axis 100, as illustrated in FIG. 3 or 5. The maximum diameter of the circular opening 120 is lower than or equal to the inner diameter tangent to openings of the plate 13. The respective openings of said other plate 12 and of the plate 13 are staggered so as to block the passage of solid and/or liquid material during the process of evaporation or sublimation of the load. In other words, in projection in a plane transverse to the axis 100, the other opening(s) 120 of said other plate 12 are offset and without intersection with the opening(s) 130 of the plate 13.

The space between each element of the lower part 21 of the filtering insert is comprised between about 1 mm and 5 mm, preferably between 2 mm and 3 mm. Advantageously, the space between each element of the lower part 21 of the filtering insert makes the cleaning between the grid 14 and said other grid 15 easier, for example by chemical cleaning. As a variant, the cleaning of the grids 14 and 15 may be made by high-temperature heating.

The size of the pores of the grid 14 is comprised between 0.1 mm and 1 mm. The size of the pores of said other grid 15 is comprised between 0.5 mm and 5 mm. Said other grid 15 is adapted to filter the solid and/or liquid material spatters of great size of the order of the mm. The grid 14 is adapted to prevent the passage of the solid and/or liquid material spatters of small size (lower than the mm) that have not been filtered by said other grid 15.

The filtering insert 70 is adapted to be inserted as a function of the crucible geometry. The elements of the filtering insert 70 maybe removable or integral with each other.

The filtering insert may be detachable and made of two distinct blocks, as for example a block comprising the upper part 20 and another block comprising the lower part 21. As a variant, the filtering insert is not-detachable and is made single-piece. However, the filtering insert is designed so as to be extractable from the crucible, in particular to change the load in the crucible.

The filtering insert has for advantage to be compatible with old evaporation cells. The filtering insert is hence able to be mounted on old evaporation cells, for example in place of a conventional insert.

The filtering insert avoids the passage of solid and/or liquid material spatters generated during the evaporation or the sublimation of the source material through the conical opening towards the substrate. Moreover, the filtering insert avoids the condensation of material on the conical opening of the insert. Conversely, the filtering insert avoids polluting the load placed in the bottom of the crucible by dusts coming for example from the deposition chamber and/or from the substrate.

Said other grid 15, the grid 14, the plate 13 and said other plate 12 let the flow of gaseous-phase material pass successively though the pores of the grids 15 and 14 then through the openings of the plates 13 and 12. The flow of gaseous-phase material is compensated for by increasing the temperature of the effusion cell.

Hence, only the flow of gaseous-phase material passes through the conical opening 11 towards the substrate 10.

The filtering insert allows filtering selectively the flow of gas while avoiding any solid and/or liquid material spatter from the crucible towards the vacuum chamber. The filtering insert protects the load placed in the crucible from any pollution by undesirable dusts or particles.

As a function of the desired application or of the size of the solid and/or liquid material spatters generated during the evaporation of the source material on the substrate, the lower part 21 of the filtering insert 70 may have different alternative configurations and comprise, from the top to the bottom:
the plate 13 having at least one opening 130 and the grid 14,
or said other plate 12 having at least one other opening 120, the plate 13 having at least one opening 130 and the grid 14,
or the plate 13 having at least one opening 130, the grid 14 and said other grid 15.

In the case where the solid and/or liquid material spatters generated during the evaporation of the source material are in small quantity, the lower part 21 of the filtering insert 70 may include the plate 13 having at least one opening 130, said other plate 12 having at least one other opening 120 and the grid 14.

Preferably, the lower part 21 of the filtering insert 70 may comprise the plate 13 having a plurality of openings and the two grids 14 and 15. In this configuration, the total surface of the openings 130 of the plate 13 represents for example 1% of the total surface of the plate 13, which allows the thermal uncoupling between the upper part and the lower part of the effusion cell 2. The grid 14 has for example pores of smaller size than the pores of said other grid 15. The combination of at least one plate and at least one grid allows preventing the passage of solid and/or liquid material while letting said flow of vapour-phase material pass through the conical opening 11.

As a variant, the lower part 21 of the filtering insert 70 may comprise the plate 13 having at least one opening 130 and the grid 14 as illustrated in FIG. 6.

A material deposition apparatus according to the present disclosure comprises a vacuum deposition chamber and the evaporation device of the present invention. The deposition chamber is provided with a vacuum pump that allows maintaining vacuum inside the chamber. The deposition chamber also comprises a support for placing the substrate 10 opposite the evaporation device and preferably sensors to measure the thickness of the deposition layer formed of the substrate.

The method for depositing a film of material on a substrate comprises the following steps:
positioning a load 3 of material to be evaporated or sublimated into the bottom of the crucible of a deposition apparatus according to the present invention,
vacuuming the chamber 1 by pumping it,
heating the crucible containing the load 3 so as to generate a flow of vapour-phase material by evaporation or sublimation of the load 3,
filtering the solid and/or liquid material by the filtering insert 70 while letting the flow of vapour-phase material pass through the conical opening 11, and
depositing the film of said vapour-phase material on the substrate 10.

The heating of the crucible transforms the solid and/or liquid load into a flow of gas that passes successively through said other grid 15, the grid 14, at least one opening 130 of the plate 13, at least one other opening 120 of said other plate 12 and the conical opening 11 of the filtering insert 70 until reaching the substrate 10.

The filtering insert 70 blocks the passage of solid and/or liquid material between the inside and the outside of the effusion cell 2 and in particular through the conical opening, the solid and/or liquid material being generated in particular during the evaporation or the sublimation of the load. The selective filtering is performed by means of the filtering insert, successively through said other grid 15, the grid 14, the plate 13 and said other plate 12, to let only the flow of gaseous-phase material pass through the conical opening 11 that controls the spatial and temporal distribution of the flow of gaseous-phase material deposited on the substrate 10.

The combination and arrangement in series of the elements of the filtering insert 70 allow improving the uniformity and homogeneity of the thin-film deposition on a substrate 10. The filtering insert 70 avoids the solid and/or liquid material spatters coming from the evaporation or the sublimation of the load towards the substrate and the walls of the vacuum deposition chamber. Moreover, the filtering insert 70 avoids the contamination of the load by dusts coming from the vacuum deposition chamber or from the substrate. The filtering insert of the present disclosure allows obtaining a material deposit of uniform thickness and composition over the whole surface of the substrate, including at a temperature lower than 1000° C. and preferably lower than 600° C.

1. An evaporation device comprising an evaporation cell (2) including heating means (4, 6) and a crucible (5) having an upper open end and a lower closed bottom, intended to receive a load (3) of material to be evaporated or sublimated, the heating means (4, 6) being adapted to heat the crucible containing the load and to generate a flow of vapour-phase material by evaporation or sublimation of the material of the load (3),
wherein the evaporation device further includes a filtering insert (70) comprising:
an upper part (20) having a conical opening (11) intended to be placed at the open end of the crucible (5), and
a lower part (21) comprising, from the top to the bottom, a plate (13) having at least one opening (130) and one grid (14), the lower part (21) being intended to be placed in the crucible (5) between the upper part (20) and the load (3).

2. The evaporation device according to claim 1, wherein the heating means comprise a first heating area (4) and a second heating area (6), the first heating area (4) being arranged in a lower part of the evaporation cell (2), the second heating area (6) being arranged in an upper part of the effusion cell (2).

3. The evaporation device according to claim 2, wherein the plate (13) is placed above the lower part of the evaporation cell (2).

4. The evaporation device according to claim 1, wherein the upper part (21) comprises, from the top to the bottom, another plate (12) having at least one other opening (120), the plate (13) having at least one opening (130) and the grid (14).

5. The evaporation device according to claim 4, wherein said at least one opening (130) of said plate (13) and said at least one other opening (120) of said other plate (12) are staggered.

6. The evaporation device according to claim 1, wherein the total surface of said at least one opening (130) of said plate (13) is lower than or equal to 1% of the surface of said plate (13).

7. The evaporation device according to claim 1, wherein the lower part (21) comprises, from the top to the bottom, said plate (13), the grid (14) and another grid (15), the grid (14) having pores of smaller size than the pores of said other grid (15).

8. The evaporation device according to claim 4, wherein the lower part (21) comprises, from the top to the bottom, said plate (13), the grid (14) and another grid (15), the grid (14) having pores of smaller size than the pores of said other grid (15).

9. The evaporation device according to claim 5, wherein the lower part (21) comprises, from the top to the bottom, said plate (13), the grid (14) and another grid (15), the grid (14) having pores of smaller size than the pores of said other grid (15).

10. The evaporation device according to claim 1, wherein the conical opening (11) of the filtering insert (70) forms a cone of revolution having a truncated apex and a base.

11. The evaporation device according to claim 4, wherein the conical opening (11) of the filtering insert (70) forms a cone of revolution having a truncated apex and a base.

12. The evaporation device according to claim 5, wherein the conical opening (11) of the filtering insert (70) forms a cone of revolution having a truncated apex and a base.

13. The evaporation device according to claim 1, wherein the filtering insert (70) comprises a cap having an opening placed around the conical opening (11) of the filtering insert (70), said cap being adapted to thermally isolate the crucible (5).

14. The evaporation device according to claim 10, wherein the filtering insert (70) comprises a cap having an opening placed around the conical opening (11) of the filtering insert (70), said cap being adapted to thermally isolate the crucible (5).

15. The evaporation device according to claim 12, wherein the filtering insert (70) comprises a cap having an opening placed around the conical opening (11) of the filtering insert (70), said cap being adapted to thermally isolate the crucible (5).

16. The evaporation device according to claim 1, further comprising fixation means (16) between the lower part (21) and the upper part (20) of the filtering insert (70).

17. The evaporation device according to claim 4, further comprising fixation means (16) between the lower part (21) and the upper part (20) of the filtering insert (70).

18. The evaporation device according to claim 7, further comprising fixation means (16) between the lower part (21) and the upper part (20) of the filtering insert (70).

19. An apparatus for depositing a film of material on a substrate (10), comprising an evaporation device according to claim 1 and a vacuum deposition chamber (1), said deposition apparatus being adapted to deposit at least one film of said vapour-phase material on a substrate (10).

20. A method for depositing a film of material on a substrate (10), comprising the following steps:
positioning a load (3) of material to be evaporated or sublimated into the bottom of the crucible (5) of a deposition apparatus according to claim 19,
vacuuming the chamber (1) by pumping it,
heating the crucible containing the load (3) so as to generate a flow of vapour-phase material by evaporation or sublimation of the load (3),
filtering solid and/or liquid material through the filtering insert (70), while letting the flow of vapour-phase material pass through the conical opening (11), and
depositing the film of said vapour-phase material on the substrate (10).
